(19) United States
(12) Patent Application Publication
(10) Pub. No.: US 2026/0280559 A1
(43) Pub. Date: Sep. 17, 2026

(54) DRIVER CIRCUIT SHARED ACROSS OPERATING MODES AND METHOD FOR OPERATING DRIVER CIRCUIT

(71) Applicant: M31 TECHNOLOGY CORPORATION, HSINCHU COUNTY (TW)

(72) Inventors: TZE-HSIANG CHAO, HSINCHU COUNTY (TW); HUI-WEN FAN, HSINCHU COUNTY (TW)

(21) Appl. No.: 19/076,837

(22) Filed: Mar. 11, 2025

(51) Int. Cl. H03K 17/687

(52) U.S. Cl. CPC H03K 17/6872

(57) ABSTRACT

A driver circuit includes a post driver and a pre-driver. The post driver includes a first switch, a resistive element and a second switch. The first switch is selectively coupled between a first supply terminal and a node. The resistive element is coupled between the node and an output terminal. The second switch is selectively coupled between a second supply terminal and the node. The pre-driver is configured to generate a control output. When the output terminal is configured to output a first voltage swing, the first supply terminal is coupled to a first voltage level, the first switch is selectively turned on according to the control output, and the second switch is turned off. When the output terminal is configured to output a second voltage swing, each supply terminal is coupled to a second voltage level, and each switch is selectively turned on according to the control output.

### PRIORITY CLAIM AND CROSS-REFERENCE

The present application claims priority to U.S. Provisional Patent Applications including Ser. No. 63/563,654, filed on Mar. 11, 2024, which is incorporated by reference herein in its entirety.

### BACKGROUND

The present disclosure relates to driver circuits and, more particularly, to a driver circuit shared across different operating modes and operating voltages, and a method for operating a driver circuit.

Communication between the memory controller and memory relies on the physical layer circuitry to ensure stable and efficient data transmission. To maintain signal integrity and minimize jitter and reflections, the driver circuits within the physical layer must support high-speed signal transmission, provide appropriate drive strength, and strictly adhere to timing requirements. Signal eye diagrams are commonly used to evaluate signal transmission quality, with the eye opening size indicating signal stability and noise immunity. For example, a larger eye opening represents higher signal contrast and better logical voltage level differentiation, enabling the receiver to more accurately determine signal states and improving data recovery reliability. Conversely, a reduced eye opening may indicate signal attenuation, reflection interference, or increased timing deviations, which degrades system performance and stability.

### SUMMARY

The described embodiments provide a driver circuit shared across different operating modes and operating voltages, and a method for operating a driver circuit.

Some embodiments described herein may include a driver circuit. The driver circuit includes a post driver and a pre-driver. The post driver has a first supply terminal, a second supply terminal and an output terminal. The post driver includes a first switch, a first resistive element and a second switch. The first switch is selectively coupled between the first supply terminal and a first node according to a control output. The first resistive element is coupled between the first node and the output terminal. The second switch is selectively coupled between the second supply terminal and the first node according to the control output. The pre-driver, coupled to the post driver, is configured to generate the control output according to a mode signal and a control input. When the mode signal indicates that the driver circuit is configured to generate an output signal having a first voltage swing at the output terminal, the first supply terminal is coupled to a first voltage level, the first switch is selectively turned on according to the control output, and the second switch is turned off. When the mode signal indicates that the driver circuit is configured to generate the output signal having a second voltage swing less than the first voltage swing, each of the first supply terminal and the second supply terminal is coupled to a second voltage level, and each of the first switch and the second switch is selectively turned on according to the control output.

Some embodiments described herein may include a driver circuit. The driver circuit includes a post driver and a pre-driver. The post driver includes an output terminal, a first switch, a first resistive element and a second switch. The first switch is selectively coupled between a first supply voltage and a first node. The first resistive element is coupled between the first node and the output terminal. The second switch is selectively coupled between the first supply voltage and the first node. The pre-driver, coupled to the post driver, is configured to receive a control input. When the first supply voltage is at a first voltage level, the pre-driver is configured to selectively turn on the first switch according to the control input, and keep the second switch turned off. When the first supply voltage is at a second voltage level lower than the first voltage level, the pre-driver is configured to selectively turn on the first switch according to the control input, and selectively turn on the second switch according to the control input.

Some embodiments described herein may include a method for operating a driver circuit. The method includes: when an output terminal of the driver circuit is configured to provide a first voltage swing, applying a supply voltage at a first voltage level to a first supply terminal and a second supply terminal of the driver circuit, selectively enabling a first conduction path between the first supply terminal and a first end of a resistive element according to a control input, and keeping a second conduction path between the second supply terminal and the first end of the resistive element disabled, wherein a second end of the resistive element is coupled to the output terminal; and when the output terminal is configured to provide a second voltage swing less than the first voltage swing, applying the supply voltage at a second voltage level to the first supply terminal and the second supply terminal, selectively enabling the first conduction path according to the control input, and selectively enabling the second conduction path according to the control input.

With the use of the proposed drive mechanism, the same driver circuit architecture can be shared across different operating modes to meet various signal specification requirements. In addition, the proposed drive mechanism can adjust the supply voltage level in response to different operating modes, addressing different application requirements for power consumption, signal integrity and bandwidth.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram illustrating an exemplary input/output unit in a physical layer circuit in accordance with some embodiments of the present disclosure.

FIG. 2 is a diagram illustrating an implementation of at least a portion of the driver circuit shown in FIG. 1 in accordance with some embodiments of the present disclosure.

FIG. 3 illustrates an implementation of the driver circuit shown in FIG. 2 in accordance with some embodiments of the present disclosure.

FIG. 4 illustrates another implementation of the driver circuit shown in FIG. 2 in accordance with some embodiments of the present disclosure.

FIG. 5 is a diagram illustrating signal waveforms associated with the driver circuit shown in FIG. 3 in accordance with some embodiments of the present disclosure.

FIG. 6 illustrates another embodiment of driver circuit shown in FIG. 2 in accordance with some embodiments of the present disclosure.

FIG. 7 is a diagram illustrating signal waveforms associated with the driver circuit shown in FIG. 6 in accordance with some embodiments of the present disclosure.

FIG. 8 illustrates another embodiment of driver circuit shown in FIG. 2 in accordance with some embodiments of the present disclosure.

FIG. 9 illustrates another embodiment of driver circuit shown in FIG. 2 in accordance with some embodiments of the present disclosure.

FIG. 10 is a flow chart of an exemplary method for operating a driver circuit in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

With advancements in memory technology, the achievable data transfer rate of memory interfaces continues to increase, thereby raising higher demands for signal integrity, power management, and design flexibility. For instance, in the Open NAND Flash Interface (ONFi) standard, center tapped termination (CTT) can ensure signal integrity during high-speed transmission but comes with higher power consumption, making it suitable for high-performance solid-state disks (SSDs) and enterprise-level storage devices. Low tapped termination (LTT) can maintain acceptable signal quality while reducing power consumption and supporting higher-speed transmission, making it more suitable for low-power embedded storage and mobile devices. Furthermore, power isolated low tapped termination (PI-LTT) can enhance the data transfer stability, further increasing the data transmission speed. However, with diverse application scenarios, single-mode architecture struggles to simultaneously meet varying requirements for power consumption, signal integrity, and bandwidth.

The present disclosure describes exemplary driver circuits, each of which can be shared across multiple operating modes and operate with one or more supply voltages corresponding to each operating mode. For example, the exemplary driver circuit may be implemented in a physical layer (PHY) circuit or an input/output (I/O) unit of a memory controller to provide signal drive capabilities adapted to different operating modes. As another example, the exemplary driver circuit may be implemented in a physical layer circuit for a NAND Flash interface to provide signal drive capabilities adapted to different operating modes. The present disclosure further describes exemplary methods for operating driver circuits to meet different application requirements in terms of power consumption, signal integrity, and bandwidth. Further description is provided below.

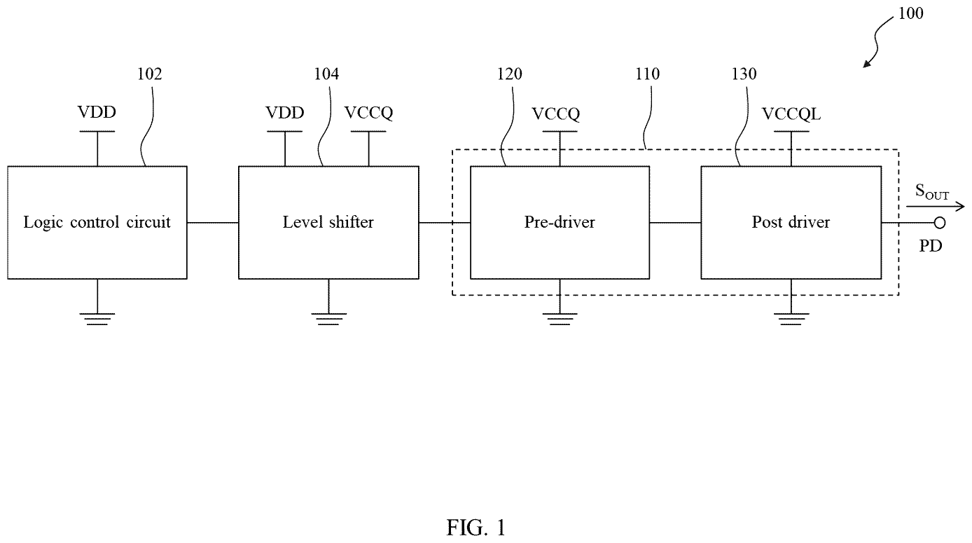

FIG. 1 is a block diagram illustrating an exemplary I/O unit in a physical layer circuit in accordance with some embodiments of the present disclosure. The I/O unit 100 may be located (but is not limited to) within a physical layer circuit between a memory controller and a memory device, such as a physical layer circuit of an Open NAND Flash Interface (ONFi). The I/O unit 100 includes, but is not limited to, a logic control circuit 102, a level shifter 104 and a driver circuit 110. The logic control circuit 102 operates within a power domain corresponding to the supply voltage VDD (e.g., a core power domain), and can be configured to receive signals from a host controller (e.g., a memory controller). The level shifter 104 can be configured to perform level shifting on signals from the logic control circuit 102, which operate in the power domain corresponding to the supply voltage VDD. The level-shifted signals operate in a power domain corresponding to the supply voltage VCCQ, such as an I/O power domain.

The driver circuit 110, powered by the supply voltage VCCQ, can be configured to generate an output signal S_{OUT} at an output terminal/pad PD according to the signals from the level shifter 104. The output signal S_{OUT} may be a data signal, a command signal, a clock signal, or other signals transmitted from the I/O pad. The output terminal PD may be connected to (but is not limited to) a termination element, such as an on-die termination (ODT). The driver circuit 110 can be configured to dynamically adjust the signal drive mechanism according to different operating modes/conditions (e.g., output voltage swing, power consumption demands, operating frequency, or termination matching requirements). For example, the driver circuit 110 may selectively enable one or more signal transmission paths according to different operating modes to thereby meet diverse signal specification requirements; different operating modes may share one or more signal transmission paths. Additionally or alternatively, in response to different operating modes, the driver circuit 110 may employ different supply voltages to generate the output signal S_{OUT}; a signal transmission path may be powered by different supply voltages in different operating modes.

The driver circuit 110 may include, but is not limited to, a pre-driver 120 and a post driver 130. The pre-driver 120 is configured to preprocess an output from the level shifter 104, thereby enhancing the drive capability of the driver circuit 110. The post driver 130 is configured to generate the output signal S_{OUT} compliant with interface specifications (e.g., ONFi specifications) according to an output from the pre-driver 120. The pre-driver 120 may be powered by the supply voltage VCCQ, and the post driver 130 may be powered by the supply voltage VCCQL. The supply voltage VCCQL can have different voltage levels in response to different operating modes/conditions to fulfill varying output signal specifications. The supply voltage VCCQ/VCCQL may be provided by a power circuit external to the I/O unit 100 (not shown), or a power circuit within a memory controller (not shown) such as a voltage regulator. Alternatively, the I/O unit 100 may include a power circuit (not shown), such as a voltage regulator, configured to generate the supply voltage VCCQL according to the supply voltage VCCQ.

By way of example but not limitation, in a first operating mode in which the I/O unit 100 (or the driver circuit 110) is configured to generate the output signal S_{OUT} having a first voltage swing, the voltage level of the supply voltage VCCQL may be equal to the voltage level of the supply voltage VCCQ. In a second operating mode in which the I/O unit 100 (or the driver circuit 110) is configured to generate the output signal S_{OUT} having a second voltage swing (less than the first voltage swing), the voltage level of the supply voltage VCCQL may differ from the voltage level of the supply voltage VCCQ. Additionally or alternatively, one or more signal transmission paths within the post driver 130 may be shared between the first operating mode and the second operating mode to generate the output signal S_{OUT} that satisfies different signal specifications.

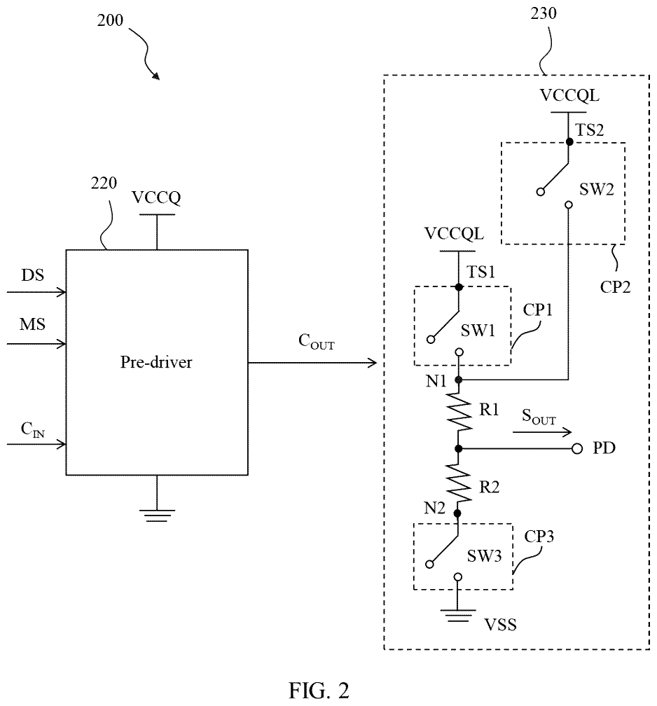

FIG. 2 is a diagram illustrating an implementation of at least a portion of the driver circuit 100 shown in FIG. 1 in accordance with some embodiments of the present disclosure. The driver circuit 200 includes, but is not limited to, a pre-driver 220 and a post driver 230. The pre-driver 220 can be used to implement at least a portion of the pre-driver 120 shown in FIG. 1, and the post driver 230 can be used to implement at least a portion of the post driver 130 shown in FIG. 1.

The post driver 230 is controlled by the pre-driver 220, and may include a supply terminal TS1, a supply terminal TS2, an output terminal PD, a resistive element R1, a switch SW1, and a switch SW2. The resistive element R1 is coupled between the node N1 and the output terminal PD. The switch SW1 is selectively coupled between the supply terminal TS1 and the node N1, and the switch SW2 is selectively coupled between the supply terminal TS2 and the node N1. When each of the supply terminals TS1 and TS2 is coupled to the supply voltage VCCQL, the switches SW1 and SW2 can be regarded as being arranged in parallel between the supply voltage VCCQL and the node N1. Each of the switches SW1 and SW2 can be arranged for selectively enabling a corresponding conduction path, such as the conduction path CP1/CP2 between the supply voltage VCCQL and the node N1.

For example, when the supply voltage VCCQL is at a first voltage level, the pre-driver 220 is configured to selectively turn on the switch SW1 according to the received control input C_{IN}, thereby selectively enabling the conduction path CP1 according to control input C_{IN}. In addition, the pre-driver 220 is configured to keep the switch SW2 turned off, thereby keeping the conduction path CP2 disabled. When the supply voltage VCCQL is at a second voltage level, the pre-driver 220 is configured to selectively turn on the switch SW1 according to the control input C_{IN}, and selectively turn on the switch SW2 according to the control input C_{IN}. In other words, when the supply voltage VCCQL is at the second voltage level, the pre-driver 220 can be configured to selectively enable the conduction path CP1 according to the control input C_{IN}, and selectively enable the conduction path CP2 according to the control input C_{IN}. The pre-driver 220 can adjust a volage level at the output terminal PD by turning on the switch SW2 when the switch SW1 is turned on, and turning off the switch SW2 when the switch SW1 is turned off.

By adjusting the number of conduction paths between the supply voltage VCCQL and the resistive element R1, the driver circuit 200 can vary the voltage swing at the output terminal PD, thus providing the output signal S_{OUT} that meets different signal specifications. In addition, the second voltage level of the supply voltage VCCQL can be configured to differ from the first voltage level thereof in response to different operating modes or design requirements. In other words, the driver circuit 200 can adjust not only the number of conduction paths between the supply voltage VCCQL and the resistive element R1 but also the voltage level of the supply voltage VCCQL in response to different operating modes, thereby generating the output signal S_{OUT} that meets predetermined signal specifications, and realizing driver architecture shared across various operating modes and/or operating voltages.

In the present embodiment, the post driver 230 may further include a resistive element R2 and a switch SW3. The resistive element R2 is coupled between the output terminal PD and the node N2. The switch SW3 is selectively coupled between the node N2 and the supply voltage VSS, thereby selectively enabling the conduction path CP3 between the node N2 and the supply voltage VSS. The voltage level of the supply voltage VSS is lower than the voltage level of the supply voltage VCCQL. For example, the supply voltage VSS has a reference voltage level lower than the first voltage level and the second voltage level of the supply voltage VCCQL; as another example, the supply voltage VSS may be implemented using a reference voltage or a ground voltage. In addition, a conduction path, formed between the output terminal PD and the supply voltage VSS, and a conduction path, formed between the supply voltage VCCQL and the output terminal PD, can be alternately enabled to generate a voltage swing at the output terminal PD. For example, when one of the switches SW1 and SW3 is turned on, the other of the switches SW1 and SW3 is turned off.

The switches SW1/SW2/SW3 may be selectively turned on according to a control output C_{OUT} generated by the pre-driver 220. For example, in the embodiment shown in FIG. 2, the pre-driver 220 may further receive an enable signal DS and a mode signal MS, and generate the control output C_{OUT} according to the enable signal DS, the mode signal MS and the control input C_{IN}. The enable signal DS can correspond to driver strength control, and can be used to selectively enable the driver circuit 200 (or the pre-driver 220). An I/O unit can achieve variable drive strength by enabling different numbers of driver circuits to meet the load requirements of different output pads.

The mode signal MS can indicate an operating mode of the driver circuit 200. By way of example but not limitation, in a first operating mode, the driver circuit 200 can be configured to output the output signal S_{OUT} having a first voltage swing according to the mode signal MS; in a second operating mode, the driver circuit 200 can be configured to output the output signal S_{OUT} with a second voltage swing according to the mode signal MS, in which the second voltage swing is less than the first voltage swing. For example, when the driver circuit 200 is applied to the ONFI 5.0 specification, the first operating mode can be a CTT mode, and the second operating mode can be an LTT mode; when the driver circuit 200 is applied to the ONFI 6.0 specification, the first operating mode can be an LTT mode, and the second operating mode can be a PI-LTT mode. However, this is not intended to limit the scope of the present disclosure. In some embodiments, the mode signal MS may indicate (or correspond to) other operating modes or conditions (e.g., different output voltage swings, power consumption requirements, operating frequencies, or termination matching requirements) without departing from the scope of the present disclosure.

In operation, when the driver circuit 200 (or the pre-driver 220) is enabled according to the enable signal DS, the pre-driver 220 can generate the control output C_{OUT} according to the mode signal MS and the control input C_{IN}. The control output C_{OUT} is used to control the operation of the post driver 230, such as the switching of the switches SW1 to SW3. When the mode signal MS indicates that driver circuit 200 is configured to generate the output signal S_{OUT} having a first voltage swing, the pre-driver 220 can turn on the switches SW1 and SW3 alternately while keeping the switch SW2 turned off, thereby producing the output signal S_{OUT} having the first voltage swing at the output terminal PD. When the mode signal MS indicates that driver circuit 200 is configured to generate the output signal S_{OUT} having a second voltage swing, the pre-driver 220 can turn on the switches SW1 and SW3 alternately, turn on the switch SW2 when the switch SW1 is turned on, and turn off the switch SW2 when the switch SW1 is turned off, thereby producing the output signal S_{OUT} having the second voltage swing at the output terminal PD.

Additionally, in some embodiments where the voltage level supplied to the post driver 230 can be adjusted according to the operating mode of the driver circuit 200, the mode signal MS may correspond to whether the supply voltage VCCQL is at a first voltage level or a second voltage level. For example, when the mode signal MS indicates the driver circuit 200 is configured to generate the output signal S_{OUT} having the first voltage swing, the supply voltage VCCQL coupled to the supply terminal TS1 is at the first voltage level. When the mode signal MS indicates the driver circuit 200 is configured to generate the output signal S_{OUT} having the second voltage swing (less than the first voltage swing), the supply voltage VCCQL coupled to the supply terminals TS1 and TS2 is at the second voltage level.

To facilitate understanding of the present disclosure, some embodiments are given below to describe the proposed drive mechanism. However, these embodiments are provided for illustrative purposes, and are not intended to limit the scope of the present disclosure. Other driver circuits capable of adjusting the supply voltage level and/or the number of drive paths according to different operating modes (or operating conditions) are also within the scope of the present disclosure.

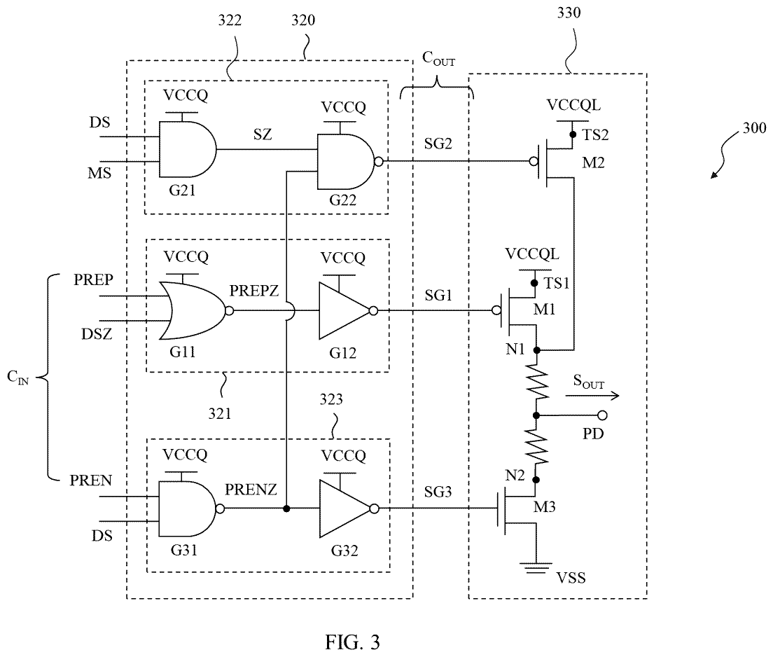

FIG. 3 illustrates an implementation of the driver circuit 200 shown in FIG. 2 in accordance with some embodiments of the present disclosure. The driver circuit 300 may include a pre-driver 320 and a post driver 330, which may serve as respective embodiments of the pre-driver 220 and the post driver 230 shown in FIG. 2. In the present embodiment, the pre-driver 320 is powered by the supply voltage VCCQ, and can be configured to generate the control output C_{OUT} according to the enable signal DS, the mode signal MS and the control input C_{IN}. The control input C_{IN} may include the input signals PREP and PREN, and the control output C_{OUT} may include the control signals SG1, SG2 and SG3. The post driver 330 is powered by the supply voltage VCCQL, and can be configured to generate the output signal S_{OUT} according to control signals SG1, SG2 and SG3.

The pre-driver 320 may include, but is not limited to, a plurality of signal generators 321 to 323. The signal generator 321 can be enabled according to the enable signal DS. The signal generator 321 is configured to, when enabled, generate the control signal SG1 according to the input signal PREP. In the embodiment shown in FIG. 3, the signal generator 321 includes, but is not limited to, a NOR gate G11 and inverter G12, each of which is powered by the supply voltage VCCQ. The NOR gate G11 is configured to generate the control signal PREPZ according to the input signal PREP and the enable signal DSZ (an inverted signal of the enable signal DS). The inverter G12 is configured to invert the control signal PREPZ to generate the control signal SG1.

The signal generator 322 can be enabled according to the enable signal DS. The signal generator 322 is configured to, when enabled, generate the control signal SG2 according to the mode signal MS and one of the input signals PREP and PREN. In the embodiment shown in FIG. 3, the signal generator 322 includes, but is not limited to, an AND gate G21 and a NAND gate G22, each of which is powered by the supply voltage VCCQ. The AND gate G21 is configured to generate the control signal SZ according to enable signal DS and the mode signal MS. The NAND gate G22 is configured to generate the control signal SG2 according to the control signal SZ and the control signal PRENZ.

The signal generator 323 can enabled according to the enable signal DS. The signal generator 323 is configured to, when enabled, generate the control signal SG3 according to the input signal PREN. In the embodiment shown in FIG. 3, the signal generator 323 includes, but is not limited to, a NAND gate G31 and an inverter G32, each of which is powered by the supply voltage VCCQ. The NAND gate G31 is configured to generate the control signal PRENZ according to the input signal PREN and the enable signal DS. The inverter G32 is configured to invert the control signal PRENZ to generate the control signal SG3.

The post driver 330 includes, but is not limited to, a plurality of transistors M1 to M3, and a plurality of resistive elements R1 and R2. The transistors M1 to M3 can represent respective embodiments of the switches SW1 to SW3 shown in FIG. 2. In the present embodiment, the transistors M1 and M2 may be implemented using p-channel transistors (e.g., such as p-channel metal-oxide-semiconductor (PMOS) transistors), while the transistor M3 may be implemented using an n-channel transistor (such as an n-channel metal-oxide-semiconductor (NMOS) transistor).

When the driver circuit 300 operates in a first mode to be configured for outputting the output signal S_{OUT} having a first voltage swing, the supply voltage VCCQL may be at a first voltage level (e.g., equal to the voltage level of the supply voltage VCCQ). The enable signal DS may have a high logic level to enable the driver circuit 300 (or the pre-driver 320), and the mode signal MS may have a low logic level to indicate that the driver circuit 300 is configured to output the output signal S_{OUT} having the first voltage swing. The signal generator 322 can generate the control signal SG2 having a logic high level according to the enable signal DS and the mode signal MS, thereby turning off the transistor M2. In addition, when each of the input signals PREP and PREN is at a high logic level, the signal generator 321 can generate the control signal SG1 having a logic high level to turn off the transistor M1, and the signal generator 323 can generate the control signal SG3 having a logic high level to turn on the transistor M3. When each of the input signals PREP and PREN is at a low logic level, the signal generator 321 can generate the control signal SG1 having a low logic level to turn on the transistor M1, and the signal generator 323 can generate the control signal SG3 having a low logic level to turn off the transistor M3. Thus, the driver circuit 300 can produce the output signal S_{OUT} having the first voltage swing in response to the input signal PREP/PREN that toggles between a high logic level and a low logic level.

When driver circuit 300 operates in a second mode to be configured for outputting the output signal S_{OUT} having a second voltage swing (less than the first voltage swing), the supply voltage VCCQL may be at a second voltage level. The enable signal DS may have a high logic level to enable the driver circuit 300 (or the pre-driver 320), and the mode signal MS may have a high logic level to indicate that the driver circuit 300 is configured to output the output signal S_{OUT} having the second voltage swing. In addition, when each of the input signals PREP and PREN is at a high logic level, the signal generator 321 can generate the control signal SG1 having a logic high level to turn off the transistor M1, the signal generator 322 can generate the control signal SG2 having a logic high level to turn off the transistor M2, and the signal generator 323 can generate the control signal SG3 having a logic high level to turn on the transistor M3. When each of the input signals PREP and PREN is at a low logic level, the signal generator 321 can generate the control signal SG1 having a low logic level to turn on the transistor M1, the signal generator 322 can generate the control signal SG2 having a low logic level to turn on the transistor M2, and the signal generator 323 can generate the control signal SG3 having a low logic level to turn off the transistor M3. In response to the input signal PREP/PREN that toggles between a high logic level and a low logic level, the driver circuit 300 can produce the output signal S_{OUT} having the second voltage swing. By turning the transistors M1 and M2 simultaneously, the driver circuit 300 can output the second voltage swing less than the first voltage swing at the output terminal PD.

By way of example but not limitation, when the driver circuit 300 is applied to the ONFi 5.0 architecture, the first mode can be a CTT mode, and the second mode can be an LTT mode. The first voltage swing may be 1.2V, and the second voltage swing may be 0.4V or 0.48V. The first voltage level and the second voltage level of the supply voltage VCCQL can be equal to the voltage level of the supply voltage VCCQ (e.g., 1.2V).

Note that, in a second mode in which the driver circuit 300 is configured to output a smaller voltage swing, the second voltage level of the supply voltage VCCQL can be lower than the first voltage level in the first mode to further reduce power consumption. By way of example but not limitation, when the driver circuit 300 is applied to the ONFi 6.0 architecture, the first mode can be an LTT mode, and the second mode can be a PI-LTT mode. The first voltage swing may be 0.4V or 0.48V, and the second voltage swing may be 0.3V. The first voltage level of the supply voltage VCCQL may be equal to the voltage level of the supply voltage VCCQ (e.g., 1.2V), while the second voltage level of the supply voltage VCCQL may be half of the first voltage level (e.g., 0.6V).

However, in an operating mode in which the supply voltage VCCQL has a lower voltage level, when the control signal SG2 undergoes a voltage transition, the drain voltage of the transistor M2 usually experiences overshoot/undershoot due to the influence of the parasitic gate-to-drain capacitance Cgd. This results in voltage glitches/spikes at the output terminal PD, which follow the voltage transitions of the control signal SG2, thereby degrading signal quality. When the transistor M2 has a larger size (i.e., a higher width-to-length ratio), the voltage glitches/spikes at the output terminal PD become more pronounced, leading to a reduced vertical eye opening of the output signal S_{OUT}.

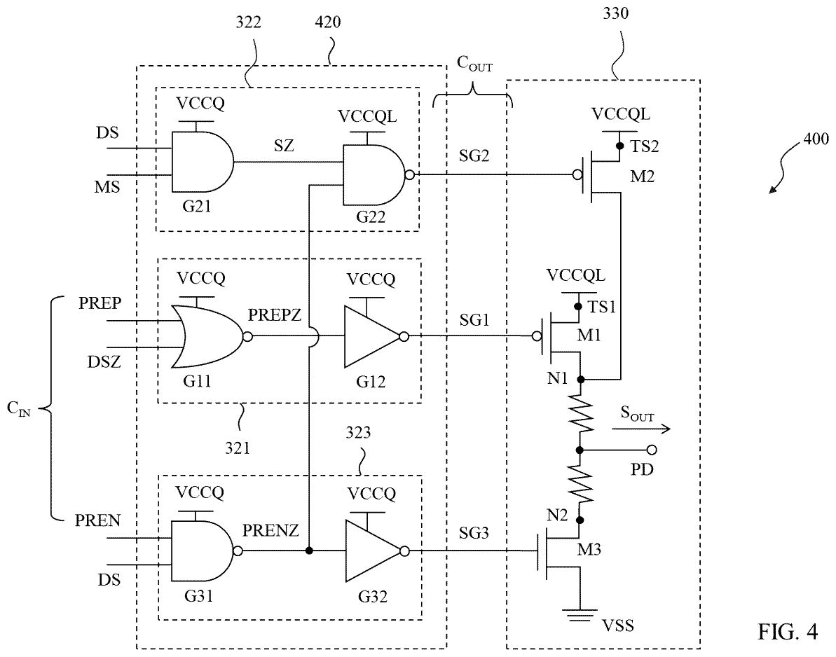

FIG. 4 illustrates another implementation of the driver circuit 200 shown in FIG. 2 in accordance with some embodiments of the present disclosure. The structure of the driver circuit 400 is substantially identical/similar to that of the driver circuit 300 shown in FIG. 3 except for the pre-driver 420. In addition, the structure of the pre-driver 420 is substantially identical/similar to that of the pre-driver 320 shown in FIG. 3 except that the NAND gate G22 shown in FIG. 4 is powered by the supply voltage VCCQL. Thus, in an operating mode where the driver circuit 400 is configured to output the output signal S_{OUT} having a second voltage swing (e.g., a voltage swing of 0.3V corresponding to a PI LTT mode), the supply voltage VCCQL is at a lower voltage level (e.g., 0.6V). This configuration lowers the maximum gate voltage of the transistor M2. However, reducing the gate voltage of the transistor M2 alone may not sufficiently improve the signal quality at the output terminal PD.

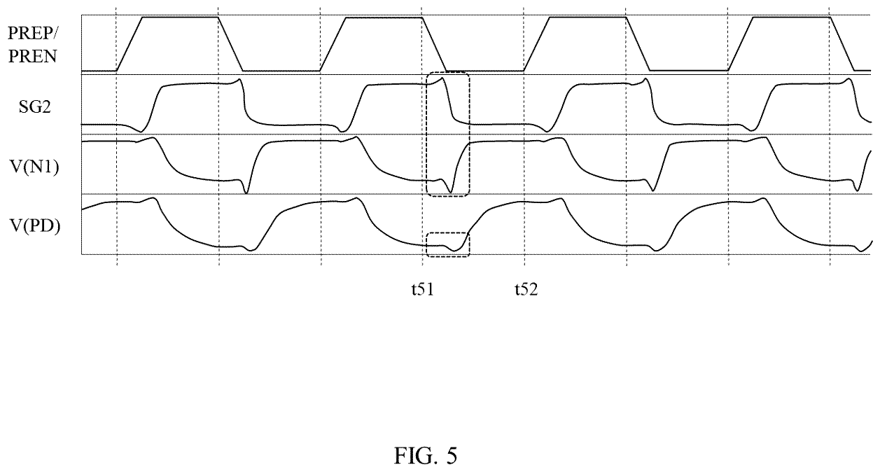

FIG. 5 is a diagram illustrating signal waveforms associated with the driver circuit 300 shown in FIG. 3 in an operating mode, in which the driver circuit 300 is configured to produce the output signal S_{OUT} having a second voltage swing (e.g., a voltage swing of 0.3V corresponding to a PI-LTT mode), in accordance with some embodiments of the present disclosure. Referring to FIG. 5 and also to FIG. 4, between time t51 and time t52, the input signal PREP/PREN transitions from a high logic level to a low logic level. Due to the parasitic capacitance Cgd of the transistor M2, both the control signal SG2 and the voltage V(N1) at the node N1 exhibit overshoot and undershoot waveforms, respectively (as indicated by the dashed rectangles). Consequently, the voltage V(PD) at the output terminal PD (i.e., the signal level of the output signal SOUT) undergoes non-ideal variations, as indicated by the dashed rectangles.

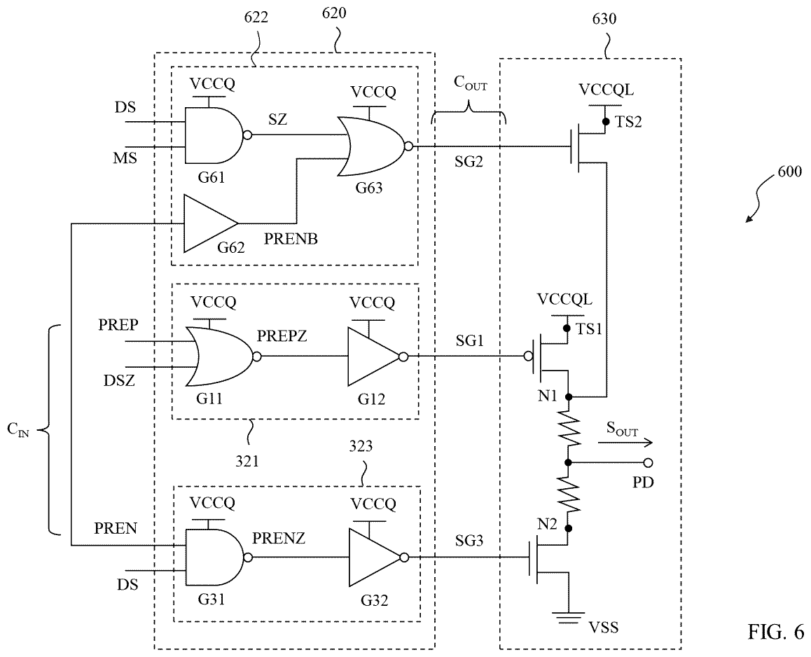

FIG. 6 illustrates another embodiment of driver circuit 200 shown in FIG. 2 in accordance with some embodiments of the present disclosure. The driver circuit 600 includes, but is not limited to, a pre-driver 620 and a post driver 630, which may serve as respective embodiments of the pre-driver 220 and the post driver 230 shown in FIG. 2.

In the present embodiment, the structure of the pre-driver 620 is substantially identical/similar to that of the pre-driver 320 shown in FIG. 3 except for the signal generator 622. The signal generator 622 includes, but is not limited to, an AND gate G61, a buffer G62 and a NOR gate G63, each of which is powered by the supply voltage VCCQ. The AND gate G61 is configured to generate the control signal SZ according to the enable signal DS and the mode signal MS; the buffer G62 is configured to produce a buffered version of the input signal PREN (i.e., the control signal PRENB); the NOR gate G63 is configured to generate the control signal SG2 according to the control signal SZ and the control signal PRENB. In addition, the post driver 630 includes the transistors M1 and M3 shown in FIG. 3, and a transistor M62 that can be implemented using an n-channel transistor (such as an NMOS transistor).

When the driver circuit 600 operates in a first mode to be configured for outputting the output signal S_{OUT} having a first voltage swing, the supply voltage VCCQL may be at a first voltage level (e.g., equal to the voltage level of the supply voltage VCCQ). The enable signal DS may have a high logic level to enable the driver circuit 600 (or the pre-driver 620), and the mode signal MS may have a low logic level to indicate that the driver circuit 600 is configured to output the output signal S_{OUT} having the first voltage swing. The signal generator 622 can generate the control signal SG2 having a low logic level according to the enable signal DS and the mode signal MS, thereby turning off the transistor M62. In addition, when each of the input signals PREP and PREN is at a high logic level, the signal generator 321 can generate the control signal SG1 having a high logic level to turn off the transistor M1, and the signal generator 323 can generate the control signal SG3 having a high logic level to turn on the transistor M3. When each of the input signals PREP and PREN is at a low logic level, the signal generator 321 can generate the control signal SG1 having a low logic level to turn on the transistor M1, and the signal generator 323 can generate the control signal SG3 having a low logic level to turn off the transistor M3. Thus, the driver circuit 600 can produce the output signal S_{OUT} having the first voltage swing in response to the input signal PREP/PREN that toggles between a high logic level and a low logic level.

When driver circuit 600 operates in a second mode to be configured for outputting the output signal S_{OUT} having a second voltage swing (less than the first voltage swing), the supply voltage VCCQL may be at a second voltage level. The enable signal DS is at a high logic level to enable the driver circuit 600 (or the pre-driver 620), and the mode signal MS may have a high logic level to indicate that the driver circuit 600 is configured to output the output signal S_{OUT} having the second voltage swing. In addition, when each of the input signals PREP and PREN is at a high logic level, the signal generator 321 can generate the control signal SG1 having a logic high level to turn off the transistor M1, the signal generator 622 can generate the control signal SG2 having a logic low level to turn off the transistor M62, and the signal generator 323 can generate the control signal SG3 having a logic high level to turn on the transistor M3. When each of the input signals PREP and PREN is at a low logic level, the signal generator 321 can generate the control signal SG1 having a logic low level to turn on the transistor M1, the signal generator 622 can generate the control signal SG2 having a logic high level to turn on the transistor M62, and the signal generator 323 can generate the control signal SG3 having a logic low level to turn off the transistor M3. In response to the input signal PREP/PREN that toggles between a high logic level and a low logic level, the driver circuit 600 can produce the output signal S_{OUT} having the second voltage swing. By turning the transistors M1 and M2 simultaneously, the driver circuit 600 can output the second voltage swing less than the first voltage swing at the output terminal PD.

By way of example but not limitation, when the driver circuit 600 is applied to the ONFi 5.0 architecture, the first mode can be a CTT mode, and the second mode can be an LTT mode. The first voltage swing may be 1.2V, and the second voltage swing may be 0.4V or 0.48V. The first voltage level and the second voltage level of the supply voltage VCCQL can be equal to the voltage level of the supply voltage VCCQ (e.g., 1.2 volts). As another example, when the driver circuit 600 is applied to the ONFi 6.0 architecture, the first mode can be an LTT mode, and the second mode can be a PI-LTT mode. The first voltage swing may be 0.4V or 0.48V, and the second voltage swing may be 0.3V. The first voltage level of the supply voltage VCCQL may be equal to the voltage level of the supply voltage VCCQ (e.g., 1.2V), while the second voltage level of the supply voltage VCCQL (e.g. 0.6V) can be lower to the first voltage level.

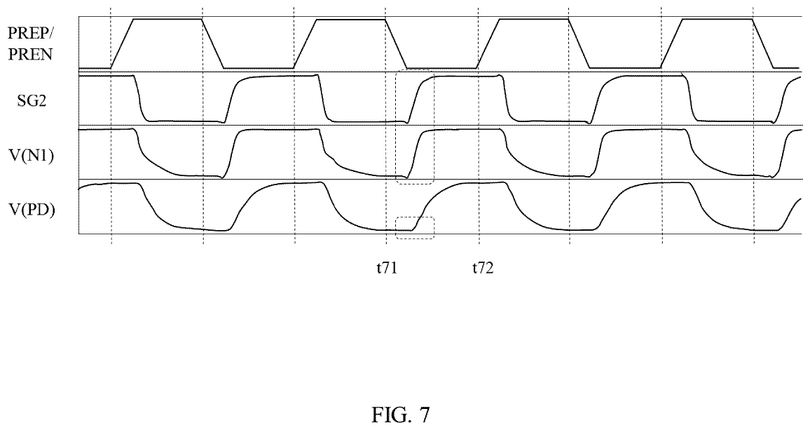

Note that, in an operating mode in which the driver circuit 600 is powered by the supply voltage VCCQL having a lower voltage level for outputting a smaller voltage swing, the output signal S_{OUT} can maintain good signal quality. FIG. 7 is a diagram illustrating signal waveforms associated with the driver circuit 600 shown in FIG. 6 in an operating mode, in which the driver circuit 600 is configured to produce the output signal S_{OUT} having a second voltage swing (e.g., a voltage swing of 0.3V corresponding to a PI-LTT mode), in accordance with some embodiments of the present disclosure. Referring to FIG. 7 and also to FIG. 6, between time t71 and time t72, the input signal PREP/PREN transitions from a high logic level to a low logic level. The respective voltage transition directions of the control signal SG2 and the voltage V(N1) at the node N1 can be aligned with the voltage transition direction of the voltage V(PD) at the output terminal PD, preventing or significantly reducing voltage glitches/spikes on the voltage V(PD) (as indicated by the dashed rectangles). Thus, the voltage V(PD) can exhibit a pronounced vertical eye opening. In other words, by utilizing an n-channel transistor to control the conductive path between the supply voltage VCCQL and the node N1 (e.g., the conductive path CP2 shown in FIG. 2), the voltage transitions of the control signal SG2 and the voltage V(N1) will not, or will almost not, exhibit overshoot/undershoot waveforms. This can mitigate the coupling effect on the output terminal PD caused by the parasitic capacitance of the p-channel transistor.

The circuit structures described above are provided for illustrative purposes, and are not intended to limit the scope of the present disclosure. In some embodiments, in an operating mode where the switch SW2 shown in FIG. 2 is kept turned off, the supply terminal TS2 may be coupled to a supply voltage different from the supply voltage VCCQL or left floating. Similarly, in an operating mode where the transistor M2 shown in FIG. 3 (or transistor M62 shown in FIG. 6) is kept turned off, the supply terminal TS2 may be coupled to a supply voltage different from the supply voltage VCCQL or be left floating.

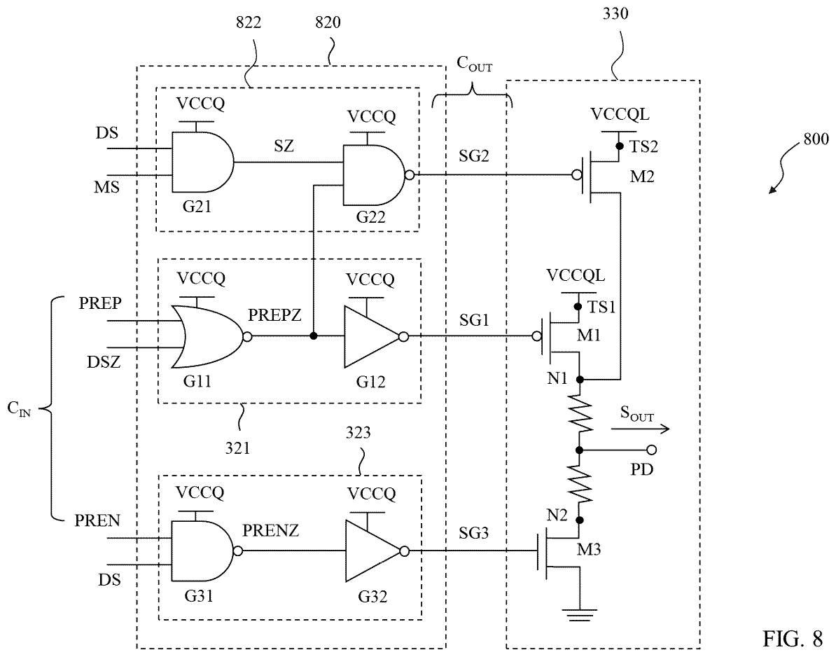

In some embodiments, the control signal SG2 provided for controlling the transistor M2 shown in FIG. 3 may be generated in response to the input signal PREP. Referring to FIG. 8, another implementation of the driver circuit 200 shown in FIG. 2 is illustrated in accordance with some embodiments of the present disclosure. The pre-driver 820, the structure of the driver circuit 800 is substantially identical/similar to that of the driver circuit 300 shown in FIG. 3 except for the pre-driver 820. In addition, the structure of the pre-driver 820 is substantially identical/similar to that of the pre-driver 320 shown in FIG. 3 except that the NAND gate G22 included in the signal generator 822 is configured to generate the control signal SG2 according to the control signal SZ and the control signal PREPZ. When the driver circuit 800 is enabled, the signal level of the control signal PREPZ is determined according to the signal level of the input signal PREP. As those skilled in the art can appreciate the operation of the driver circuit 800 after reading the above paragraphs directed to FIG. 1 to FIG. 7, further description is omitted here for brevity.

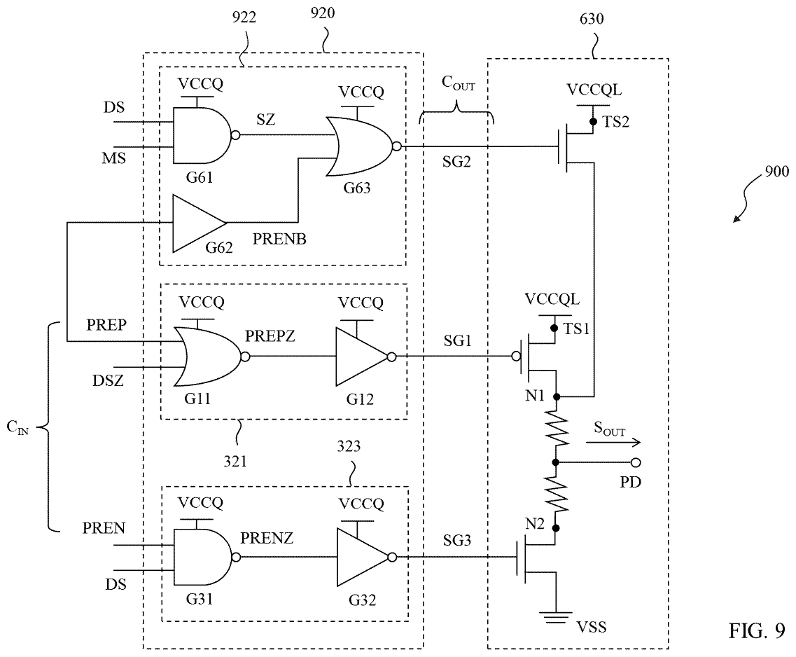

In some embodiments, the control signal SG2 provided for controlling the transistor M62 shown in FIG. 6 may be generated in response to the input signal PREP. Referring to FIG. 9, another implementation of the driver circuit 200 shown in FIG. 2 is illustrated in accordance with some embodiments of the present disclosure. The structure of driver circuit 900 is substantially identical/similar to that of the driver circuit 600 shown in FIG. 6 except for the pre-driver 920. In addition, the structure of the pre-driver 920 is substantially identical/similar to that of the pre-driver 620 shown in FIG. 6 except that the buffer G62 included in the signal generator 922 is configured to generate the control signal PREPZ according to the input signal PREP. As those skilled in the art can appreciate the operation of the driver circuit 900 after reading the above paragraphs directed to FIG. 1 to FIG. 8, further description is omitted here for brevity.

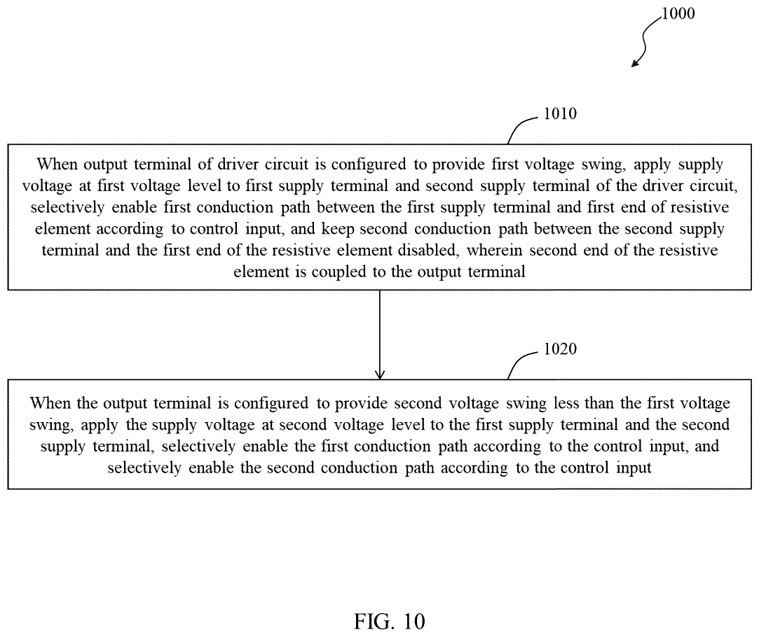

FIG. 10 is a flow chart of an exemplary method for operating a driver circuit in accordance with some embodiments of the present disclosure. The method 1000 is described with reference to the driver circuit 200 shown in FIG. 2 for illustrative purposes. Those skilled in the art should appreciate that the method 1000 can be employed in the driver circuit 300 shown in FIG. 3, the driver circuit 400 shown in FIG. 4, the driver circuit 600 shown in FIG. 6, the driver circuit 800 shown in FIG. 8, the driver circuit 900 shown in FIG. 9, or other driver circuits capable of output different voltage swings without departing from the scope of the present disclosure. Additionally, in some embodiments, other operations in the method 1000 can be performed. In some embodiments, operations of the method 1000 can be performed in a different order and/or vary.

At operation 1010, when an output terminal of the driver circuit is configured to provide a first voltage swing, a supply voltage at a first voltage level is applied to a first supply terminal and a second supply terminal of the driver circuit, a first conduction path between the first supply terminal and a first end of a resistive element is selectively enabled according to a control input, and a second conduction path between the second supply terminal and the first end of the resistive element is kept disabled. A second end of the resistive element is coupled to the output terminal.

Consider an example where the driver circuit 200 is applied to the ONFi 5.0 architecture. When the output terminal PD is configured to provide a voltage swing of 1.2V corresponding to the CTT mode, each of the supply terminals TS1 and TS2 can be coupled to the supply voltage VCCQL at 1.2V. The pre-driver 220 can selectively enable the conduction path CP1 according to the control input C_{IN} and keep the conduction path CP2 disabled. Consider another example where the driver circuit 200 is applied to the ONFi 6.0 architecture. When the output terminal PD is configured to provide a voltage swing of 0.4V or 0.48V corresponding to the LTT mode, each of the supply terminals TS1 and TS2 can be coupled to the supply voltage VCCQL at 1.2V. The pre-driver 220 can selectively enable the conduction path CP1 according to the control input C_{IN} and keep the conduction path CP2 disabled.

At operation 1020, when the output terminal is configured to provide a second voltage swing less than the first voltage swing, the supply voltage at a second voltage level is applied to the first supply terminal and the second supply terminal, the first conduction path is selectively enabled according to the control input, and the second conduction path is selectively enabled according to the control input.

Consider an example where the driver circuit 200 is applied to the ONFi 5.0 architecture. When the output terminal PD is configured to provide a voltage swing of 0.4V or 0.48V corresponding to the LTT mode, each of the supply terminals TS1 and TS2 can be coupled to the supply voltage VCCQL at 1.2V. The pre-driver 220 can selectively enable the conduction path CP1 according to the control input C_{IN}, and selectively enable the conduction path CP2 according to the control input C_{IN}. Consider another example where the driver circuit 200 is applied to the ONFi 6.0 architecture. When the output terminal PD is configured to provide a voltage swing of 0.3V corresponding to the PI-LTT mode, each of the supply terminals TS1 and TS2 can be coupled to the supply voltage VCCQL at 0.6V. The pre-driver 220 can selectively enable the conduction path CP1 according to the control input C_{IN}, and selectively enable the conduction path CP2 according to the control input C_{IN}. The conduction path CP2 can be implemented using an n-channel transistor, such as the transistor M62 shown in FIG. 6.

In some embodiments, when the output terminal is configured to provide the second voltage swing, the second conduction path is enabled when the first conduction path is enabled, and is disabled when the first conduction path is disabled. Consider an example where the driver circuit 200 is applied to the ONFi 5.0 architecture. When the output terminal PD is configured to provide a voltage swing of 0.4V or 0.48V corresponding to the LTT mode, the conduction path CP2 can be enabled when the conduction path CP1 is enabled, and can be disabled when the conduction path CP1 is disabled. Consider another example where the driver circuit 200 is applied to the ONFi 6.0 architecture. When the output terminal PD is configured to provide a voltage swing of 0.3V corresponding to the PI-LTT mode, the conduction path CP2 can be enabled when the conduction path CP1 is enabled, and can be disabled when the conduction path CP1 is disabled.

In some embodiments, the conduction path CP3 can be selectively enabled according to the control input C_{IN}, thereby adjusting the voltage at the output terminal PD. For example, when one of the conduction paths CP1 and CP3 is enabled, the other of the conduction paths CP1 and CP3 is disabled. As those skilled in the art would readily understand the operation of the method 1000 after reading the above paragraphs directed to FIG. 1 to FIG. 9, further description is omitted here for brevity.

With the use of the proposed drive mechanism, the same driver circuit architecture can be shared across different operating modes to meet various signal specification requirements. In addition, the proposed drive mechanism can adjust the supply voltage level in response to different operating modes, addressing different application requirements for power consumption, signal integrity and bandwidth.

As used herein, the terms “substantially” are used to describe and account for small variations. When used in conduction with an event or circumstance, the terms can refer to instances in which the event of circumstance occurs precisely as well as instances in which the event or circumstance occurs to a close approximation. As used herein with respect to ta given value or range, the term “substantially” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. In addition, when referring to numerical values or characteristics as “substantially” the same, the term can refer to the values lying within ±10%, ±5%, ±1%, or ±0.5% of an average of the values.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A driver circuit, comprising:
a post driver, having a first supply terminal, a second supply terminal and an output terminal, the post driver comprising:
a first switch, selectively coupled between the first supply terminal and a first node according to a control output;
a first resistive element, coupled between the first node and the output terminal; and
a second switch, selectively coupled between the second supply terminal and the first node according to the control output; and
a pre-driver, coupled to the post driver, the pre-driver being configured to generate the control output according to a mode signal and a control input,
wherein when the mode signal indicates that the driver circuit is configured to generate an output signal having a first voltage swing at the output terminal, the first supply terminal is coupled to a first voltage level, the first switch is selectively turned on according to the control output, and the second switch is turned off; when the mode signal indicates that the driver circuit is configured to generate the output signal having a second voltage swing less than the first voltage swing, each of the first supply terminal and the second supply terminal is coupled to a second voltage level, and each of the first switch and the second switch is selectively turned on according to the control output.

2. The driver circuit of claim 1, wherein the second voltage level is lower than the first voltage level.

3. The driver circuit of claim 1, wherein when the driver circuit is configured to generate the output signal having the second voltage swing, the second switch is turned on when the first switch is turned on, and is turned off when the first switch is turned off.

4. The driver circuit of claim 1, wherein the first switch is a p-channel transistor, and the second switch is an n-channel transistor.

5. The driver circuit of claim 1, wherein when the driver circuit is configured to generate the output signal having the first voltage swing, the second supply terminal is coupled to the first voltage level.

6. The driver circuit of claim 1, wherein the post driver further comprises:
a third switch, selectively coupled between a second node and a reference voltage level according to the control output, wherein the reference voltage level is less than each of the first voltage level and the second voltage level; and
a second resistive element, coupled between the output terminal and the second node.

7. The driver circuit of claim 6, wherein when one of the first switch and the third switch is turned on, the other of the first switch and the third switch is turned off.

8. The driver circuit of claim 6, wherein the control input comprises a first input signal and a second input signal; the control output comprises a first control signal, a second control signal and a third control signal; the pre-driver comprises:
a first signal generator, configured to generate the first control signal according to the first input signal, wherein the first switch is controlled by the first control signal;
a second signal generator, configured to generate the second control signal according to the mode signal and one of the first input signal and the second input signal, wherein the second switch is controlled by the second control signal; and
a third signal generator, configured to generate the third control signal according to the second input signal, wherein the third switch is controlled by the third control signal.

9. A driver circuit, comprising:
a post driver, comprising:
an output terminal;
a first switch, selectively coupled between a first supply voltage and a first node;
a first resistive element, coupled between the first node and the output terminal; and
a second switch, selectively coupled between the first supply voltage and the first node; and
a pre-driver, coupled to the post driver, the pre-driver being configured to receive a control input, wherein when the first supply voltage is at a first voltage level, the pre-driver is configured to selectively turn on the first switch according to the control input, and keep the second switch turned off; when the first supply voltage is at a second voltage level lower than the first voltage level, the pre-driver is configured to selectively turn on the first switch according to the control input, and selectively turn on the second switch according to the control input.

10. The driver circuit of claim 9, wherein when the supply voltage is at the first voltage level, the post driver is configured to generate an output signal having a first voltage swing; when the supply voltage is at the second voltage level, the post driver is configured to generate an output signal having a second voltage swing less than the first voltage swing.

11. The driver circuit of claim 9, wherein when the supply voltage is at the second voltage level, the second switch is turned on when the first switch is turned on, and is turned off when the first switch is turned off.

12. The driver circuit of claim 9, wherein the first switch is a p-channel transistor, and the second switch is an n-channel transistor.

13. The driver circuit of claim 9, wherein the post driver further comprises:
a third switch, selectively coupled between a second node and a second supply voltage, wherein a voltage level of the second supply voltage is less than each of the first voltage level and the second voltage level; and
a second resistive element, coupled between the output terminal and the second node.

14. The driver circuit of claim 13, wherein when one of the first switch and the third switch is turned on, the other of the first switch and the third switch is turned off.

15. The driver circuit of claim 13, wherein the control input comprises a first input signal and a second input signal; the pre-driver is further configured to receive a mode signal corresponding to whether the first supply voltage is at the first voltage level or the second voltage level; the pre-driver comprises:
a first signal generator, configured to generate a first control signal according to the first input signal, wherein the first switch is controlled by the first control signal;
a second signal generator, configured to generate a second control signal according to the mode signal and one of the first input signal and the second input signal, wherein the second switch is controlled by the second control signal; and
a third signal generator, configured to generate a third control signal according to the second input signal, wherein the third switch is controlled by the third control signal.

16. A method for operating a driver circuit, comprising:
when an output terminal of the driver circuit is configured to provide a first voltage swing, applying a supply voltage at a first voltage level to a first supply terminal and a second supply terminal of the driver circuit, selectively enabling a first conduction path between the first supply terminal and a first end of a first resistive element according to a control input, and keeping a second conduction path between the second supply terminal and the first end of the first resistive element disabled, wherein a second end of the first resistive element is coupled to the output terminal; and
when the output terminal is configured to provide a second voltage swing less than the first voltage swing, applying the supply voltage at a second voltage level to the first supply terminal and the second supply terminal, selectively enabling the first conduction path according to the control input, and selectively enabling the second conduction path according to the control input.

17. The method of claim 16, wherein the second voltage level is lower than the first voltage level.

18. The method of claim 16, wherein when the output terminal is configured to provide the second voltage swing, the second conduction path is enabled when the first conduction path is enabled, and is disabled when the first conduction path is disabled.

19. The method of claim 16, wherein the step of selectively enabling the second conduction path according to the control input comprises:
selectively turning on an n-channel transistor placed in the second conduction path according to the control input, wherein the second conduction path is enabled when the n-channel transistor is turned on, and is disabled when the n-channel transistor is turned off.

20. The method of claim 16, further comprising:
selectively enabling a third conduction path between a first end of a second resistive element and a reference voltage according to the control input, wherein a second end of the second resistive element is coupled to the output terminal;
wherein when one of the first conduction path and the third conduction path is enabled, the other of the first conduction path and the third conduction path is disabled.
